(19) United States
(12) Patent Application Publication
(10) Pub. No.: US 2017/0033305 A1
(43) Pub. Date: Feb. 2, 2017

(54) METAL PARTICLE ENHANCED FORSTER RESONANCE ENERGY TRANSFER FOR ORGANIC OPTOELECTRONIC DEVICE

(71) Applicant: INTERNATIONAL BUSINESS MACHINES CORPORATION, Armonk, NY (US)

(72) Inventors: Cheng-Wei Cheng, White Plains, NY (US); Jeehwan Kim, Los Angeles, CA (US); Ning Li, White Plains, NY (US); Kuen-Ting Shiu, Yorktown Heights, NY (US)

(21) Appl. No.: 14/815,556

(22) Filed: Jul. 31, 2015

(51) Int. Cl. H01L 51/44; H01L 51/42

(52) U.S. Cl. CPC H01L 51/447; H01L 51/426; H01L 51/442; Y10S 977/774; Y10S 977/893; Y10S 977/948; B82Y 20/00

(57) ABSTRACT

A photovoltaic device that includes an organic or quantum dot sensitizer layer for absorbing light spectra and providing excitons. The sensitizer layer may include metal particles embedded therein for increased exciton transfer efficiency. The photovoltaic device may further include a junction comprising an electron donor layer and electron acceptor layer for charge carrier transport.

### BACKGROUND

Technical Field

The present disclosure relates to photovoltaic devices, such as solar cells, and more particularly to solar cells that employ Forster resonance energy transfer (FRET) principles.

Description of the Related Art

Solar cells, also called photovoltaic (PV) devices, are a type of photosensitive optoelectronic device that is specifically used to generate electrical power. PV devices, which may generate electrical energy from light sources other than sunlight, can be used to drive power consuming loads to provide, for example, lighting, heating, or to power electronic circuitry or devices such as calculators, radios, computers or remote monitoring or communications equipment. These power generation applications also often involve the charging of batteries or other energy storage devices so that operation may continue when direct illumination from the sun or other light sources is not available, or to balance the power output of the PV device with a specific application's requirements.

### SUMMARY

In one embodiment, the present disclosure provides an organic photovoltaic device that includes an organic sensitizer layer for absorbing light spectra and providing excitons, wherein the sensitizer layer comprises metal particles embedded therein for increased exciton transfer efficiency; and a junction comprising an electron donor layer and electron acceptor layer for charge carrier transport.

In another embodiment, an photovoltaic device is provided includes an sensitizer layer including quantum dots for absorbing light spectra and providing excitons, wherein the sensitizer layer further comprises metal particles embedded therein for increased exciton transfer efficiency; and at least one material layer for charge carrier transport.

In another aspect of the present disclosure of method is provided for increasing the exciton transfer efficiency of sensitizer layers in organic photovoltaic devices. In some embodiments, the method may include forming a junction comprising an electron donor layer and an electron acceptor layer, wherein at least one of the donor layer and the electron acceptor layer comprises an organic material. In a following step, an organic sensitizer layer is formed on the electron donor layer of the junction, the organic sensitizer layer comprising metal particles embedded therein for increased exciton transfer efficiency.

### BRIEF DESCRIPTION OF DRAWINGS

The disclosure will provide details in the following description of preferred embodiments with reference to the following figures wherein:

FIG. 1 is a side cross-sectional view depicting one embodiment of an organic solar cell that employs Forster resonance energy transfer (FRET) principles and includes metal particles embedded in the sensitizing layer for increased exciton transfer efficiency, in accordance with one embodiment of the present disclosure.

FIG. 2 is a plot illustrating the band absorption of organic compositions used in solar cells that is due to discrete energy levels, in accordance with some embodiments of the present disclosure.

FIG. 3 is a plot illustrating the effect of metal particle size on exciton resonant wavelength.

FIG. 4 is a side cross-sectional view depicting another embodiment of an organic solar cell that employs Forster resonance energy transfer (FRET) principles and includes metal particles embedded in the sensitizing layer for increased exciton transfer efficiency, in which light absorption materials of the cell have been separated from the charge transfer materials of the cell, in accordance with the present disclosure.

FIG. 5 is a side cross-sectional view depicting one embodiment of an organic solar cell that employs Forster resonance energy transfer principles (FRET) and includes quantum dots, as well as metal particles embedded in the sensitizing layer for increased exciton transfer efficiency, in accordance with the present disclosure.

FIG. 6 is a side cross-sectional view depicting another embodiment of an organic solar cell that employs Forster resonance energy transfer principles and includes quantum dots, as well as metal particles embedded in the sensitizing layer for increased exciton transfer efficiency, in accordance with the present disclosure.

### DETAILED DESCRIPTION OF PREFERRED EMBODIMENTS

Detailed embodiments of the methods and structures of the present disclosure are described herein; however, it is to be understood that the disclosed embodiments are merely illustrative of the disclosed methods and structures that may be embodied in various forms. In addition, each of the examples given in connection with the various embodiments of the disclosure are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. For purposes of the description hereinafter, the terms “upper”, “lower”, “right”, “left”, “vertical”, “horizontal”, “top”, “bottom”, and derivatives thereof shall relate to the invention, as it is oriented in the drawing figures. The terms “overlying”, “atop”, “positioned on” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

The present disclosure is related to apparatuses and methods including metal particle enhanced Forster resonance energy transfer (FRET) for organic optoelectronic devices. Excitonic solar cells, such as devices using organic materials and inorganic nanocrystals have many advantages, such as low cost and tunable material properties. However, the power conversion efficiency of these devices can be improved, as per the present disclosure. Among some of the challenges that have been recognized include broadening the light absorption spectra. For example, some of the typical materials used in solar cells absorb only a relatively narrow band of photon energy. Another challenge is achieving high light absorption efficiency and charge collection efficiency at the same time. Typical solar cell materials are either good at light absorbing or charge transporting, but materials having both of these desirable traits are not conventional. It has been determined that these problems can be overcome if excitons can be transferred between multiple materials, so that materials with different absorption and transporting properties can be integrated into the same device.

The methods and apparatuses of the present disclosure use metal particle enhanced Forster Resonance Energy Transfer (FRET) in excitonic solar cells to enhance the FRET radius and efficiency. Forster Resonance Energy Transfer (FRET) is a non-radiative process whereby an excited state donor transfers energy to a proximal ground state acceptor. A donor, initially in its electronic excited state, may transfer energy to an acceptor through non-radiative dipole-dipole coupling. The efficiency of this energy transfer is inversely proportional to the sixth power of the distance between donor and acceptor, making FRET extremely sensitive to small changes in distance. The function of the metal particles is to enhance the optical mode density and the resonance between the molecules or nanocrystals around the particles. Many order of magnitude enhancement of the FRET efficiency and many times enhancement of the FRET radius have been observed using the methods and apparatus of the present disclosure.

In some embodiments, the methods and apparatus disclosed herein employ metal particles to enhance the FRET performance of solar cells to promote exciton transfer between different materials. An exciton is a bound state of an electron and an electron hole which are attracted to each other by the electrostatic Coulomb force. By integrating materials with different properties, including materials with high absorption coefficients, materials with different absorption bands, materials with high carrier transport mobilities, etc., in the same device, the methods and apparatuses disclosed herein can (1) enhance the optical absorption and spectrum coverage with multiple absorbing materials, and (2) use different materials for light absorption and charge transport to enhance the efficiency of both processes. As a result, the solar cell power conversion efficiency can be improved.

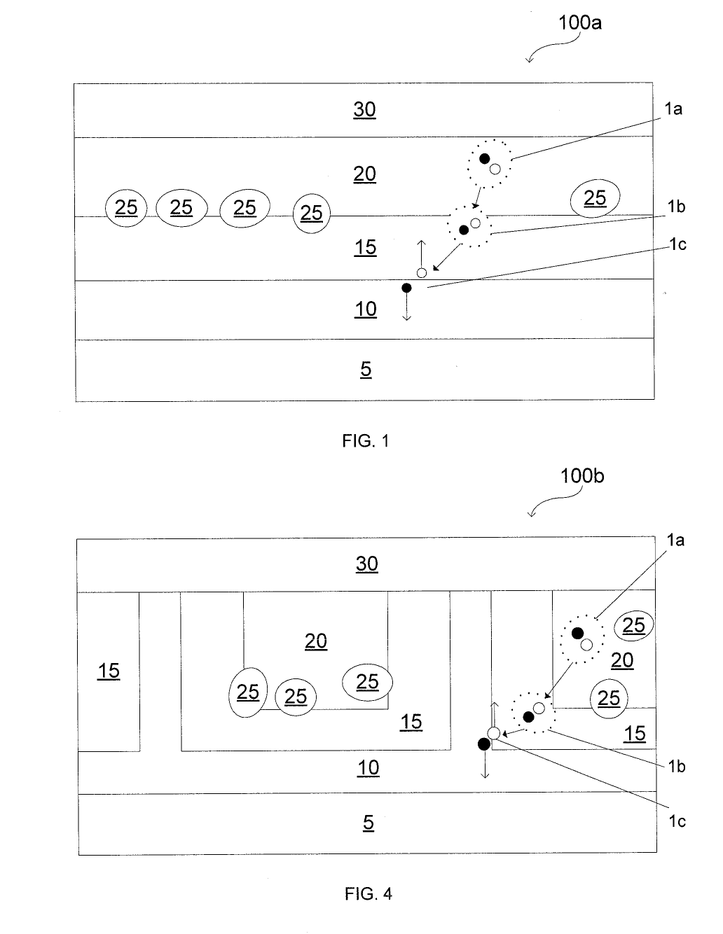

In accordance with some embodiments of the present disclosure, the above disadvantages of prior FRET solar cells are overcome by embedding metal particles within the solar cell, such as embedding the metal particles in the sensitizer layer of the solar cell. The metal particles increase the exciton transfer efficiency of the sensitizer layer of the solar cell. By “increased exciton transfer efficiency” it is meant that the exciton transfer efficiency for a solar cell including the embedded metal particles is greater than an identically structured and composition solar cell that does not include the embedded metal particles. For example, the exciton transfer efficiency a sensitizer layer having metal particles present therein may range from 10% to 100%. Further details regarding the solar cells that are consistent with some embodiments of the present disclosure in further detail with reference to FIGS. 1-6.

FIG. 1 depicts one embodiment of an organic photovoltaic device 100a that includes an organic sensitizer layer 20 for absorbing light spectra and providing excitons, wherein the organic sensitizer layer 20 comprises metal particles 25 embedded therein for increased exciton transfer efficiency, and a junction comprising an electron donor layer 15 and electron acceptor layer 10 for charge carrier transport.

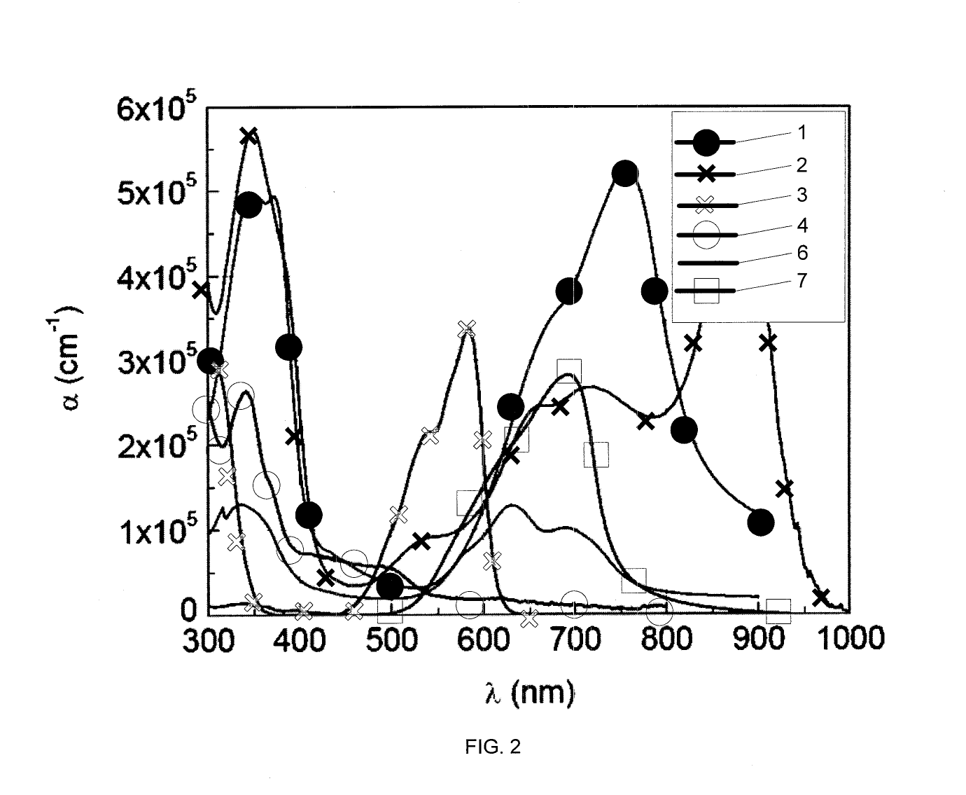

In a Forster Resonance Energy Transfer (FRET) solar cell, sensitizing materials are added to the device, i.e., added to an absorption layer (hereafter referred to as organizing sensitizer layer 20), to enhance the absorption spectra. Organic molecules have relatively narrow band absorption due to discrete energy levels. FIG. 2 depicts the multiple materials are needed to broaden the absorption spectral range and also enhance the absorption amplitude for organic solar cells. For example, the plot having reference number 1 is a plot for band absorption of an organic material layer of chloroaluminum phthalocyanine (ClAlPc) for use in solar cells. The plot having reference number 2 is a plot for band absorption of an organic material layer of tin (II) phthalocyanine (SnPc) for use in solar cells. The plot having reference number 3 is a plot for band absorption of an organic material layer of subphthalocyanine (SubPc) for use in solar cells. The plot having reference number 4 is a plot for band absorption of an organic material layer of carbon 60 (C60) for use in solar cells. The plot having reference number 6 is a plot for band absorption of an organic material layer of copper phthalocyanine (CuPc) for use in solar cells. The plot having reference number 7 is a plot for band absorption of an organic material layer of squaraine (SQ) for use in solar cells.

In view of the multiple band absorption envelopes of organic solar cells, multiple materials are typically needed to broaden the absorption spectral range and also enhance the absorption amplitude for the organic solar cells. Using FRET principles, sensitizing materials can be added into the device, i.e., the organic sensitizer layer 20, to enhance the absorption spectra and amplitude. For example, in some embodiments, the organic sensitizer layer 20 may be composed of chloroaluminum phthalocyanine (ClAlPc), phenyl-C61-butyric acid methyl ester (PCBM), tin (II) phthalocyanine (SnPc), subphthalocyanine (SubPc), carbon 60 (C60), copper phthalocyanine (CuPc), squaraine (SQ) or a combination thereof.

In some embodiments, during operation of the solar cell 100a, light contacting, i.e., photons incident to, the organic sensitizer layer 20 having an energy that exceeds the band gap of the material of the organic sensitizer layer 20 excites an electron to an unoccupied state above the band gap, which creates an electron-hole (e-h pair). In polymer solar cells as disclosed herein, the electron-hole pair which was created through absorption is held together by coulomb forces, forming a quasi-particle, which is referred to herein as an “exciton” 1a.

In some embodiments, the methods and structures disclosed herein integrated metal particles 25 into the solar cell 100a to enhance the exciton transfer efficiency from the sensitizer layer 20. Although not wishing to be bound, in some embodiments, the enhanced exciton transfer efficiency is believed to result from the metal particle 25 enhancing the optical mode density and enhancing the dipole coupling between the modules in the organic sensitizer layer 20. For example, the exciton transfer efficiency a sensitizer layer having metal particles 25 present therein may range from 10% to 100%. In another example, the exciton transfer efficiency a sensitizer layer 20 having metal particles 25 present therein may range from 50% to 100%.

The metal particles 25 that provide for increased exciton transfer efficiency may include silver (Ag), aluminum (Al), copper (Cu), gold (Au), tungsten (W), platinum (Pt), tantalum (Ta), titanium (Ti), gold (Au) or a combination thereof. It is noted that the aforementioned compositions for the metal particles 25 are provided for illustrative purposes only, and are not intended to limit the present disclosure to only the above described examples. Any metal particle that may be integrated with the organic sensitizer layer 20 and increase exciton formation, e.g., by enhancing the optical mode density and enhancing the dipole coupling between the modules in the organic sensitizer layer 20, may be suitable for use with the present disclosure.

In some embodiments, the particle size, e.g., particle diameter, of the metal particles 25 may contribute to the efficiency of exciton transfer. In some embodiments, the particle size of the metal particles 25 may range from 20 nm to 200 nm. In some examples, the particle size of the metal particles 25 may be equal to 25 nm, 30 nm, 35 nm, 40 nm, 45 nm, 50 nm, 60 nm, 70 nm, 80 nm, 90 nm, 100 nm, 110 nm, 120 nm, 130 nm, 140 nm, 150 nm, 155 nm, 160 nm, 165 nm, 170 nm, 175 nm, 180 nm, 185 nm, 190 nm, and 200 nm. Further, in some examples, the particle size may be equal to any value within a range including an upper limit and a lower limit selected from the aforementioned examples. The wavelengths absorbed by a sensitizer layer 20 having metal particles 25 with sizes in the aforementioned range may extend from approximately 500 nm to 1100 nm.

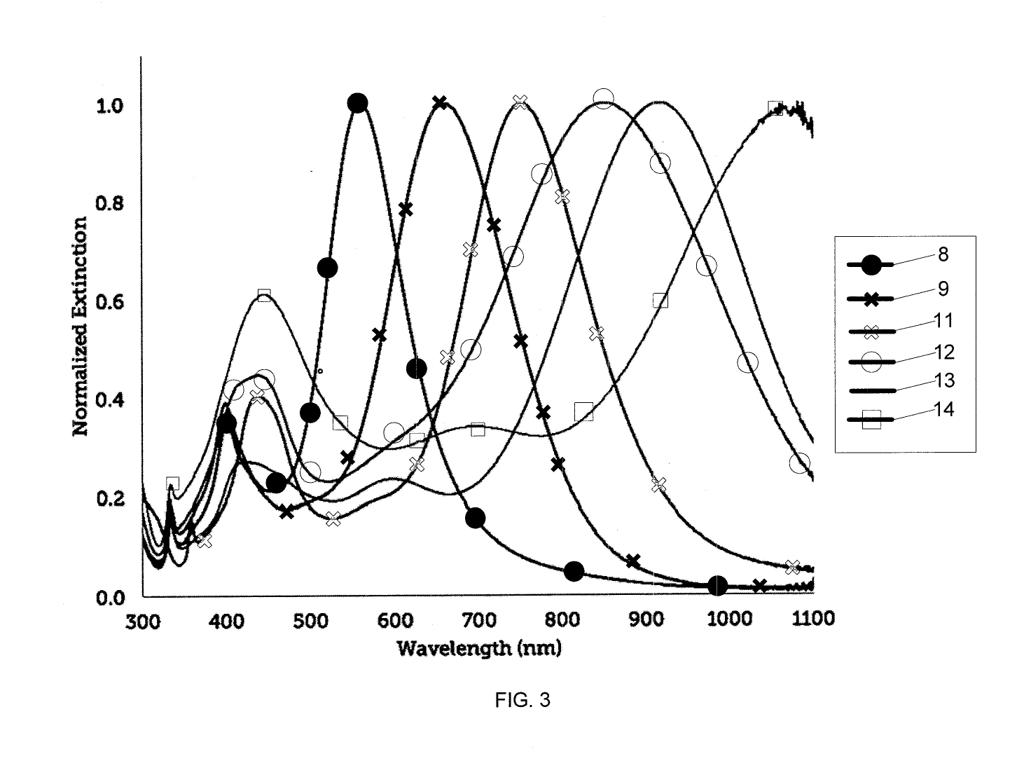

FIG. 3 is a plot illustrating the extinction of wavelengths measured from resonant wavelengths corresponding to the particle size of the metal particles 25 integrated with the sensitizer layer 20. The plot line identified by reference number 8 is for a resonant wavelength of 550 nm and a metal particle size ranging from 40 nm to 60 nm. The plot line identified by reference number 9 is for a resonant wavelength of 650 nm and a metal particle size ranging from 60 nm to 80 nm. The plot line identified by reference number 11 is for a resonant wavelength of 750 nm and a metal particle size ranging from 80 nm to 100 nm. The plot line identified by reference number 12 is for a resonant wavelength of 850 nm and a metal particle size ranging from 100 nm to 130 nm. The plot line identified by reference number 13 is for a resonant wavelength of 950 nm and a metal particle size ranging from 110 nm to 150 nm. The plot line identified by reference number 14 is for a resonant wavelength of 1050 nm and a metal particle size ranging from 120 nm to 170 nm.

In some embodiments, the concentration of the metal particles 25 can contribute to the efficiency of exciton transfer. More specifically, the concentration of the metal particles 25 should be selected so that enough particles are present to provide for enhanced Forster Resonance Energy Transfer (FRET) while not providing such a high concentration of metal particles which would obstruct the transmission of light through the solar cell. In some embodiments, the metal particles 25 are dispersed at a concentration so that the spacing between adjacent metal particles 25 ranging from 50 nm and 200 nm. In other embodiments, the spacing between adjacent metal particles 25 may range from 75 nm to 175 nm. In yet another embodiment, the spacing between adjacent metal particles 25 may range from 100 nm to 125 nm. It is noted that the above examples of ranges for the spacing between adjacent metal particles is provided for illustrative purposes only, and that other ranges may also be within the scope of the present disclosure, as long as the particle spacing facilitates FRET performance without negatively impacting the performance of the solar cell.

In some embodiments, the metal particles 25 are provided as a substantially discontinuous layer at the interface of the organic sensitizer layer 20 and the electron donor layer 15 of the junction for the solar cell 100a. In other embodiments, the metal particles 25 may be distributed throughout the thickness of the organic sensitizer layer 20. In yet other embodiments, the metal particle 25 are distributed throughout the organic sensitizer layer 20 with a greatest concentration of metal particles 25 at the interface of the electron donor layer 10 and the organic sensitizer layer 20.

Referring to FIG. 1, in some embodiments, the junction layers of the solar cell 100a include the electron donor layer 15 and the electron acceptor layer 10. The donor level (also referred to as electron donor layer) is the level of the solar cell 100a that donates conduction electrons to the system. The term “acceptor” as used in the phrase electron acceptor layer 10 denotes a material that has fewer outer shell electrons than required in an otherwise balanced structure, providing a hole, which can accept a free electron. In one embodiment, the electron donor layer 15 is an n-type conductivity material, and the electron acceptor layer is a p-type conductivity layer, wherein at least one of the electron donor layer and the electron acceptor layer has an organic composition. In some embodiments, the electron donor layer 15 comprises chloroaluminum phthalocyanine (ClAlPc), tin (II) phthalocyanine (SnPc), subphthalocyanine (SubPc), carbon 60 (C60), copper phthalocyanine (CuPc), squaraine (SQ) or a combination thereof, and the electron acceptor layer 10 comprises phenyl-C61-butyric acid methyl ester (PCBM), carbon 60 (C60), or a combination thereof. It is noted that in some embodiments, at least one of the electron donor layer 15 and the electron acceptor layer 10 may be composed of an inorganic semiconductor material, such as silicon (Si)

In some embodiments, exciton dissociation 1b and charge transport 1c functions of the solar cell occur within the layers of the junction, i.e., the electron acceptor layer 10 and the electron donor layer 15. As described above, a photon incident on the organic sensitizer layer, having a high enough energy creates an electron-hole (e-h) pair 1a. The electron-hole 1a pair is subsequently separated over a built-in gradient in the electrochemical potential of the solar cell provided by the junction, i.e., the electron acceptor layer 10 and the electron donor layer 15. Finally, the electron and hole is collected at opposite electrodes and led to recombine after being put to work in an external circuit.

Referring to FIG. 1, the solar cell typically includes electrodes, i.e., an anode 30 and cathode 5. The anode 30 and cathode 5 may each be composed of an electrically conductive material. The anode 30 may be in direct contact with the organic sensitizer layer 25. The anode 30 is typically composed of a material that provides for a high transmission of light. In some examples, the anode 30 may be composed of indium tin oxide (ITO), due to a high optical transmission combined with a low resistance. The cathode 5 may be in direct contact with the electron acceptor layer 10. Similar to the anode 30, the cathode 5 may also be composed of indium tin oxide (ITO). In other embodiments, the cathode 5 may be composed of a metal, such as aluminum (Al), copper (Cu), platinum (Pt), gold (Au), silver (Ag) and combinations thereof.

Although not depicted in the supplied figures, the solar cell 100a may further include a supporting substrate. For example, when making polymer solar cells the substrates used for supporting the layered solar cell stack, can be divided into two distinct groups: glass and plastics. The two most commonly used types being floated glass substrates with ITO transparent electrodes and flexible PET foil, where the transparent electrodes are either ITO as for the glass substrates or printed transparent electrodes.

The solar cell 100a that is depicted in FIG. 1 includes active layers, i.e., the organic sensitizer layer 20, the electron donor layer 15, and the electron acceptor layer 10 that are planar. The planar organic sensitizer layer enhances absorption. This is only one geometry of a solar cell that is suitable for use with the present disclosure. The present disclosure is not limited to only this geometry. Any geometry for the active layers of the solar cell is suitable so long as the geometry selected does not substantially degrade the performance of the device.

For example, FIG. 4 depicts another geometry of a solar cell 100b that includes metal particles 25 for enhancing Forster Resonance Energy Transfer (FRET) characteristics, in which the light absorption materials, e.g., organic sensitizer layer 20, are separated from the charger carrier transport materials, e.g., electron donor layer 15 and electron acceptor layer 10. Referring to FIG. 4, the electron donor layer 15 and the electron acceptor layer 10 include vertical and horizontally disposed portions, which are arranged in a U-shaped geometry. The organic sensitizer layer 10 may be deposited in well type geometries filling the U-shaped electron donor layers 15. The FRET performance of the solar cell 100b depicted in FIG. 4 is similar to the FRET performance of the solar cell 100a depicted in FIG. 1. For example, the solar cell 100b depicted in FIG. 4 includes metal particles 25 embedded within an organic sensitizer layer 20 for increased exciton transfer efficiency. With the exception of the difference in the geometry of the active layers between the solar cell 100b depicted in FIG. 4 and the solar cell 100a depicted in FIG. 1, the solar cells 100a, 100b have similar anodes 30, organic sensitizer layers 20, metal particles 25, electron donor layers 15, electron acceptor layers 10 and cathodes 5. Therefore, the description of the anode 30, organic sensitizer layer 20, metal particle 25, electron donor layer 15, electron acceptor layer 10 and cathode 5 depicted in FIG. 1 is suitable for at least one embodiment of the anode 30, organic sensitizer layer 20, metal particle 25, electron donor layer 15, electron acceptor layer 10 and cathode 5 of the solar cell 100b depicted in FIG. 4.

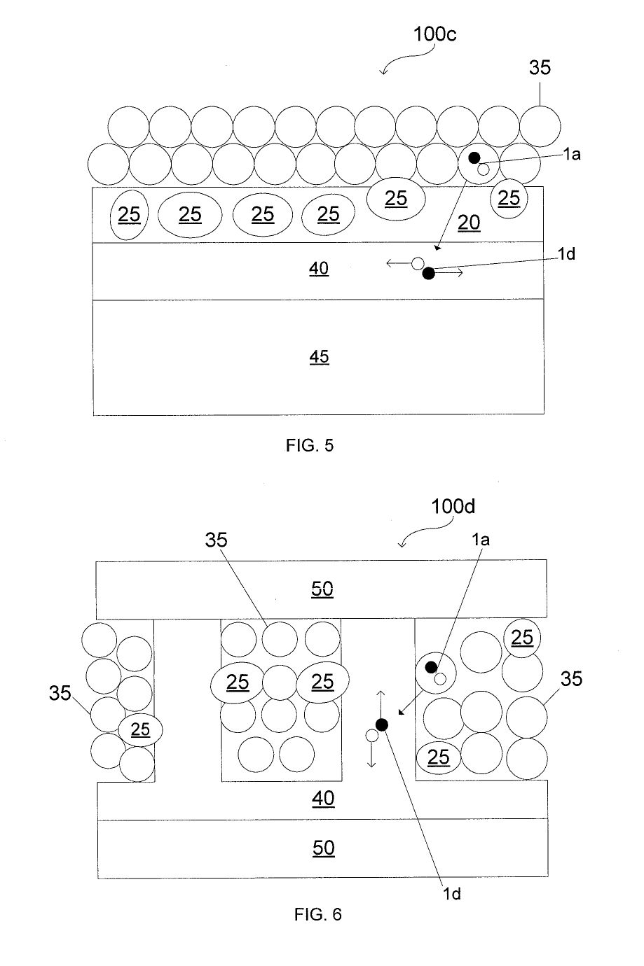

In other embodiments of the present disclosure, enhanced charge transport and optical absorption for solar cells 100c, 100d may be achieved using nanocrystal or quantum dot absorbers, as depicted in FIGS. 5 and 6. Similar to organic solar cells, nanocrystal and quantum dot solar cells can benefit from broadening the absorption spectra and enhancing charge carrier collection, which can be achieved using Forster Resonance Energy Transfer (FRET) principles. For example, in the embodiments depicted in FIGS. 5 and 6 the FRET process can occur between quantum confined materials with high energy gaps to quantum confined materials with low energy gap quantum dots, or from quantum confined material to bulk materials. Broadening of the optical absorption spectra and increased charge carrier collection can be provided by embedding metal particles in a sensitizer layer. The metal particles enhance the exciton transfer efficiency from the sensitizer layer, as described above with respect to the solar cells 100a, 100b depicted in FIGS. 1 and 4.

FIG. 5 depicts one embodiment of an quantum dot solar cell 100c that employs Forster resonance energy transfer (FRET) principles and includes quantum dots 25, as well as metal particles 25 embedded in the sensitizer layer 20 for increased exciton transfer efficiency 1a, 1d (including exciton 1a formation). The quantum dot solar cell 100c depicted in FIG. 5 includes a plurality of quantum dots 35, a sensitizer layer 20 including a plurality of metal particles 25 a high mobility material layer 40 and a substrate 45. Quantum dots 35 are nanoparticles typically composed of periodic groups of III-V or II-VI semiconductor materials such as ZnS, ZnSe, CdS, CdSe, CdTe, InP, and others. Their reduced size induces a shift of the electronic excitations to higher energy. A quantum dot solar cell is a solar cell design that uses quantum dots as at least a portion of the absorbing photovoltaic material. Quantum dots 35 have bandgaps that are tunable across a wide range of energy levels by changing the dots' size.

In some embodiments, the quantum dots 35 employed in the quantum dot solar cell 100c depicted in FIG. 5 may have a composition selected from the group consisting of MgO, MgS, MgSe, MgTe, CaO, CaS, CaSe, CaTe, SrO, SrS, SrSe, SrTe, BaO, BaS, BaSe, BaTe, ZnO, ZnS, ZnSe, ZnTe, CdO, CdS, CdSe, CdTe, HgO, HgS, HgSe, HgTe, Al₂O₃, Al₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, SiO₂, GeO₂, SnO₂, SnS, SnSe, SnTe, PbO, PbO₂, PbS, PbSe, PbTe, AlN, AlP, AlAs, AlSb, GaN, GaP, GaAs, GaSb, InN, InP, InAs, InSb or combinations thereof. Each of the quantum dots 35 can have a particle size ranging from 1 nm to 50 nm. In some embodiments, the quantum dots 35 can have a particle size ranging from 1 nm to 10 nm. In some embodiments, the quantum dots are substantially spherical.

The sensitizer layer 20 (also referred to as a capping layer) that the plurality of quantum dots 35 is present on may be similar to the sensitizer layer 20 that is described above with reference to FIG. 1. For example, the sensitizer layer 20 may be composed of an organic material and may have metal particles embedded therein, in which the metal particles 25 provide for increased exciton transfer efficiency. For example, the sensitizer layer 20 may be composed of chloroaluminum phthalocyanine (ClAlPc), phenyl-C61-butyric acid methyl ester (PCBM), tin (II) phthalocyanine (SnPc), subphthalocyanine (SubPc), carbon 60 (C60), copper phthalocyanine (CuPc), squaraine (SQ) or a combination thereof.

The metal particles 25 that are employed in the quantum dot solar cell 100c depicted in FIG. 5 are similar to the metal particles 25 that have been described above with reference to FIG. 1. For example, the metal particles 25 employed in the quantum dot solar cell 100c depicted in FIG. 5 may be composed of silver (Ag), aluminum (Al), copper (Cu), gold (Au), tungsten (W), platinum (Pt), tantalum (Ta), titanium (Ti), gold (Au) or a combination thereof. Further details for the metal particles 25 depicted in FIG. 5 can be found in the description of the metal particles 25 that are depicted in FIG. 1. For example, the metal particles may have a particle size ranging from 20 nm to 200 nm, in which the metal particles are dispersed in organic sensitizer layer 20 the to provide a spacing between adjacent metal particles ranging from 50 nm and 200 nm.

The high mobility material layer 40 provides for charge transport 1d in the quantum dot solar cell 100c. For example, the exciton dissociation and charge transport functions 1d of the solar cell 100c occur within high mobility material layer 40. In some embodiments, the high mobility material layer 40 comprises an electron donor layer and an electron acceptor layer. The electron donor layer may be composed of chloroaluminum phthalocyanine (ClAlPc), tin (II) phthalocyanine (SnPc), subphthalocyanine (SubPc), carbon 60 (C60), copper phthalocyanine (CuPc), squaraine (SQ) or a combination thereof, and the electron acceptor layer may be composed of phenyl-C61-butyric acid methyl ester (PCBM), carbon 60 (C60), or a combination thereof. In some embodiments, at least one material layer in the high mobility material layer 40 may be composed of an inorganic material, such as a silicon containing semiconductor layer, such as silicon (Si).

Still referring to FIG. 5, in some embodiments, the quantum dot solar cell 100c may further include a substrate 45. In some examples, the substrate 45 may be composed of glass, a polymeric material, or a semiconductor material. The substrate 45 may be rigid, but flexible substrates are also within the scope of the present disclosure. Although not depicted in FIG. 5, the quantum dot solar cell 100c may also include electrodes, e.g., an anode and a cathode. For example, an anode may be in electrical communication with the portion of the solar cell 100c containing the quantum dots 35 and organic sensitizer layer 20, which in one example may be composed of indium tin oxide (ITO). A cathode may be in electrical communication with the high mobility material layer 40. In some examples, the cathode may be positioned on a surface of the substrate, or the cathode may function as the substrate of the solar cell 100c. The cathode can be compose of a metal, or may be composed of indium tin oxide (ITO).

FIG. 6 depicts another embodiment of a quantum dot solar cell 100d that employs Forster resonance energy transfer principles and includes quantum dots 35, as well as metal particles 25 for increased exciton transfer efficiency 1a. In the solar cell 100d that is depicted in FIG. 6, the high mobility material layer 40 is not planar, as depicted in FIG. 5, but instead has been patterned to provide a plurality of trenches. The trenches in the high mobility material layer 40 can be substantially filled with at least one of quantum dots 35 and metal particles 25. The quantum dots 35 and metal particles 25 provide for phonon absorption and the formation of excitons. In some embodiments, the exciton dissociation and charge transport functions 1d of the solar cell 100d occur within high mobility material layer 40.

The composition and dimensions of the quantum dots 35 that have been provided above in the description of the quantum dots 35 depicted in FIG. 5 is suitable for the description of the quantum dots depicted in FIG. 6.

The metal particles 25 may be directly intermixed with the quantum dots 35, or the metal particles 25 may be integrated in a sensitizer layer (not shown in FIG. 6) that is present on the horizontal and vertical surfaces of the high mobility material layer 40. The metal particles 25 that are depicted in FIG. 6 are similar to the metal particles 25 that have been described above with reference to FIG. 1, FIG. 4 and FIG. 5. The sensitizing layer has also been described above, i.e., sensitizing layer 20, with reference to FIG. 1. The descriptions of the metal particles 25 and sensitizing layer 20 provided above are suitable for the descriptions of these features as embodied in FIG. 6.

The high mobility layer 40 that is depicted in FIG. 6 includes pillar portions that extend between the electrodes 50. The trenches containing the metal particles 25 and quantum dots 35 are present between these pillars. The composition of the high mobility layer 40 that is depicted in FIG. 6 is similar to the composition of the high mobility layer 40 that is depicted in FIG. 5. Therefore, the description of the high mobility layer 40 that is depicted in FIG. 5 is suitable for the description of at least one embodiment of the high mobility layer 40 that is depicted in FIG. 6.

The electrodes 50 may be composed of an electrically conductive material such at indium tin oxide (ITO) or a metal.

In another aspect of the present disclosure, a method for increasing the exciton 1a transfer efficiency in organic photovoltaic devices is provided. Referring to FIG. 1, in some embodiments, the method for forming the solar cell 100a may include forming a junction comprising an electron donor layer 15 and an electron acceptor layer 10; and forming an organic sensitizer layer 20 on the electron donor layer 10 of the junction, in which the organic sensitizer layer 20 comprising metal particles 25 embedded therein for increased exciton transfer efficiency, i.e., exciton formation 1a, exciton dissociation 1b and charge transport 1c.

The junction including the electron donor layer 15 and the electron acceptor layer 10 may be formed from at least one organic material. The organic materials for the electron donor layer 15 and the electron acceptor layer 10 may be deposited from chemical solution using a process such as spin on deposition. In some embodiments, the junction may be formed on supporting substrate, in which an electrode, such as a cathode 5, may be formed on the supporting substrate prior to forming the junction. The electrode may be formed using chemical vapor deposition (CVD) or physical vapor deposition (PVD). PVD methods for forming electrodes can include plating, such as electroplating or electroless plating.

In some embodiments, forming the organic sensitizer layer 20 includes forming the metal particles 25, mixing the metal particles 25 with a dispersion of polymeric precursor for the organic sensitizer layer 20, and depositing the dispersion containing the metal particles 25 on the junction. The metal particles 25 may be formed using a physical vapor deposition process, such as sputtering. In some embodiments, depositing the dispersion containing the metal particles 25 comprises spin casting. In another embodiment, forming of the organic sensitizer layer 20 may include depositing a thin layer of metal on the junction, and depositing an organic sensitizer layer 20 on the thin layer of metal.

Following formation of the organic sensitizer layer 20, an anode 30 may be forming. The anode 30 may be composed of indium tin oxide (ITO) that is deposited on the upper surface of the organic sensitizer layer 20. The anode 30 may be deposited using chemical vapor deposition (CVD), atomic layer deposition (ALD) or physical vapor deposition (PVD), such as sputtering.

The method for forming the solar cell 100b depicted in FIG. 4 is similar to the above described method of forming the solar cell 100a depicted in FIG. 1, with the exception that the method for forming the solar cell 100b depicted in FIG. 4 may include an additional photolithography and etch step. More specifically, a photolithography and etch step may be applied to the electron acceptor layer 10 following its deposition to introduce topography to the layer prior to depositing the electrode donor layer 15.

In yet another embodiment, a method of forming a solar cell including quantum dots 35, such as the quantum dot solar cell 100c depicted in FIG. 5, is also provide by the present disclosure. In some embodiments, the method for forming the solar cell 100c depicted in FIG. 5 may begin with forming the high mobility material layer 40 on the substrate 45, using a deposition method, such as spin on deposition or spin casting for the organic material compositions that provide the high mobility material layer 40. In some embodiments, an electrode, such as a cathode may be formed on the substrate 45 prior to depositing the high mobility material layer 40. In a following process step, the organic sensitizer layer 20 and the metal particles 25 may be formed atop the high mobility material layer 40. In some embodiments, the method that is described for forming the metal particles 25 and organic sensitizer layer 20 that is depicted in FIG. 1 is equally applicable to the method for forming the metal particles 25 and organic sensitizer layer 20 that is depicted in FIG. 5.

In a following process step, the quantum dots 35 may be formed on the layer including the metal particles 25 and organic sensitizer 20. The quantum dots 35 may be formed as colloidal semiconductor nanocrystals that are synthesized from precursor compounds dissolved in solutions. The synthesis of colloidal quantum dots is done by using precursors, organic surfactants, and solvents. Heating the solution at high temperature, the precursors decompose forming monomers which then nucleate and generate nanocrystals. Self-assembled quantum dots may nucleate spontaneously under certain conditions during molecular beam epitaxy (MBE) and metal organic vapor phase epitaxy (MOVPE), when a material is grown on a substrate to which it is not lattice matched. The resulting strain produces coherently strained islands on top of a two-dimensional wetting layer. This growth mode is known as Stranski-Krastanov growth. The quantum dots 35 may also be formed using electrochemical assembly or high temperature dual injection methods. An anode may be formed to the quantum dots 35.

The quantum dot solar cell 100d depicted in FIG. 6 may be formed using similar methods as the process flow that has been described above for forming the solar cell 100c depicted in FIG. 5. In one embodiment, to provide the solar cell 100d depicted in FIG. 6, the high mobility layer 40 is deposited on an electrode 50, and is patterned using photolithography, and etched to provide a plurality of pillars defining trenches. The trenches may then be filled with quantum dots 35 and metal particles 25. In the embodiments, in which the metal particles 25 are integrated with an organic sensitizer layer, the composite material may be formed using the methods described above for providing the organic sensitizer layer 20 that is depicted in FIGS. 1, 4 and 5. A second electrode may then be formed in contact with the upper surface of the pillar portions of the high mobility layer 40.

Methods as described herein may be used in the fabrication of integrated circuit chips and/or solar cells. The resulting integrated circuit chips or cells can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes photovoltaic devices, integrated circuit chips with solar cells, ranging from toys, calculators, solar collectors and other low-end applications to advanced products.

Having described preferred embodiments for methods and structures directed to metal particle enhanced Forster resonance energy transfer in organic optoelectronic devices (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. An photovoltaic device comprising;
an organic sensitizer layer for absorbing light spectra and providing excitons, wherein the sensitizer layer comprises metal particles embedded therein for increased exciton transfer efficiency; and
a junction comprising an electron donor layer and electron acceptor layer for charge carrier transport.

2. The photovoltaic device of claim 1, wherein the organic sensitizer layer comprises chloroaluminum phthalocyanine (ClAlPc), phenyl-C61-butyric acid methyl ester (PCBM), tin (II) phthalocyanine (SnPc), subphthalocyanine (SubPc), carbon 60 (C60), copper phthalocyanine (CuPc), squaraine (SQ) or a combination thereof.

3. The photovoltaic device of claim 1, wherein the metal particles comprise silver (Ag), aluminum (Al), copper (Cu), gold (Au), tungsten (W), platinum (Pt), tantalum (Ta), titanium (Ti), gold (Au) or a combination thereof.

4. The photovoltaic device of claim 1, wherein the metal particles have a particle size ranging from 20 nm to 200 nm.

5. The photovoltaic device of claim 1, wherein the metal particles are dispersed to provide a spacing between adjacent metal particles ranging from 50 nm and 200 nm.

6. The photovoltaic device of claim 1, further comprising an anode in direct contact with a surface of the organic sensitizer layer that is opposite a surface of the organic sensitizer layer that is present on the electron donor layer.

7. The photovoltaic device of claim 6 further comprising a cathode on a surface of the junction that is opposite the surface of the junction that the organic sensitizer layer is present on.

8. The photovoltaic device of claim 1, wherein the electron donor layer is an n-type semiconductor material, and the electron acceptor layer is a p-type semiconductor layer, wherein at least one of the electron donor layer and the electron acceptor layer has an organic composition.

9. The photovoltaic device of claim 1, wherein the electron donor layer comprises chloroaluminum phthalocyanine (ClAlPc), tin (II) phthalocyanine (SnPc), subphthalocyanine (SubPc), carbon 60 (C60), copper phthalocyanine (CuPc), squaraine (SQ) or a combination thereof, and the electron acceptor layer comprises phenyl-C61-butyric acid methyl ester (PCBM), carbon 60 (C60), or a combination thereof.

10. The photovoltaic device of claim 1, wherein the metal particles are proximate to an interface between the organic sensitizer layer and the electron donor layer.

11. A solar cell device comprising:
an sensitizer layer including quantum dots for absorbing light spectra and providing excitons, wherein the sensitizer layer further comprises metal particles embedded therein for increased exciton transfer efficiency; and
a layer for charge carrier transport.

12. The solar cell device of claim 11, wherein the sensitizer layer comprises chloroaluminum phthalocyanine (ClAlPc), phenyl-C61-butyric acid methyl ester (PCBM), tin (II) phthalocyanine (SnPc), subphthalocyanine (SubPc), carbon 60 (C60), copper phthalocyanine (CuPc), squaraine (SQ) or a combination thereof, and the layer for charge carrier transport comprises an electron donor layer and an electron acceptor layer, the electron donor layer comprising chloroaluminum phthalocyanine (ClAlPc), tin (II) phthalocyanine (SnPc), subphthalocyanine (SubPc), carbon 60 (C60), copper phthalocyanine (CuPc), squaraine (SQ) or a combination thereof, and the electron acceptor layer comprising phenyl-C61-butyric acid methyl ester (PCBM), carbon 60 (C60), or a combination thereof.

13. The solar cell device of claim 11, wherein the metal particles comprise silver (Ag), aluminum (Al), copper (Cu), gold (Au), tungsten (W), platinum (Pt), tantalum (Ta), titanium (Ti), gold (Au) or a combination thereof.

14. The solar cell device of claim 11, wherein the metal particles have a particle size ranging from 20 nm to 200 nm.

15. The solar cell device of claim 11, wherein the metal particles are dispersed to provide a spacing between adjacent metal particles ranging from 50 nm and 200 nm.

16. The solar cell device of claim 11, wherein the quantum dots have a composition comprising MgO, MgS, MgSe, MgTe, CaO, CaS, CaSe, CaTe, SrO, SrS, SrSe, SrTe, BaO, BaS, BaSe, BaTe, ZnO, ZnS, ZnSe, ZnTe, CdO, CdS, CdSe, CdTe, HgO, HgS, HgSe, HgTe, Al₂O₃, Al₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, SiO₂, GeO₂, SnO₂, SnS, SnSe, SnTe, PbO, PbO₂, PbS, PbSe, PbTe, AlN, AlP, AlAs, AlSb, GaN, GaP, GaAs, GaSb, InN, InP, InAs, InSb or combinations thereof.

17. A method for increasing the exciton transfer efficiency of sensitizer layers in photovoltaic devices comprising:
forming a junction comprising an electron donor layer and an electron acceptor layer, wherein at least one of the donor layer and the electron acceptor layer comprises an organic material; and
forming an organic sensitizer layer on the electron donor layer of the junction, the organic sensitizer layer comprising metal particles embedded therein for increased exciton transfer efficiency.

18. The method of claim 17, wherein the forming the organic sensitizer layer comprises:
forming the metal particles;
mixing the metal particles with a dispersion of polymeric precursor for the organic sensitizer layer; and
depositing the dispersion containing the metal particles on the junction.

19. The method of claim 18, wherein said depositing the dispersion containing the metal particles comprises spin casting.

20. The method of claim 17, wherein the forming of the organic sensitizer layer comprises depositing a thin layer of metal on the junction, and depositing an organic sensitizer layer on the thin layer of metal.
